(19) United States
(12) Patent Application Publication
(10) Pub. No.: US 2004/0238858 A1
(43) Pub. Date: Dec. 2, 2004

(54) Semiconductor device and a method of manufacturing the same

(76) Inventors: Yasushi Haga, Sakata-shi (JP); Muneyoshi Hama, Sakata-shi (JP)

Correspondence Address: HARNESS, DICKEY & PIERCE, P.L.C., P.O. BOX 828, BLOOMFIELD HILLS, MI, 48303, US

(21) Appl. No.: 10/798,970

(22) Filed: Mar. 11, 2004

(30) Foreign Application Priority Data
Mar. 14, 2003 (JP) 2003-070552

(51) Int. Cl. H01L 27/148

(52) U.S. Cl. 257/232

(57) ABSTRACT

[Problem]To reduce a leakage current by suppressing the generation of a junction leakage.

[Means to Solve the Problem]A semiconductor device comprises: a semiconductor region 103, in which an impurity of one conductivity type is doped; a gate insulation layer 105, formed on the semiconductor region 103; a gate electrode 106, formed on the gate insulation layer 105; a lightly doped layer 109a, formed in a region from the principal surface of the semiconductor region 103 to a first depth, in which a first impurity of the other conductivity type is implanted into the semiconductor region 103 with a first dose amount; and a heavily doped layer 109b, formed in a region from the principal surface of the semiconductor region 103 to a second depth, which is shallower than the first depth, in which a second impurity of the other conductivity type is implanted into the semiconductor region 103 with a second dose amount in a range of the first dose amount or more to 1×10E15/cm² or less.

### DETAILED DESCRIPTION OF THE INVENTION

1. Field of the Invention

The present invention relates to a semiconductor device suitable for a MOS transistor and a method of manufacturing the same.

2. Description of the Prior Art

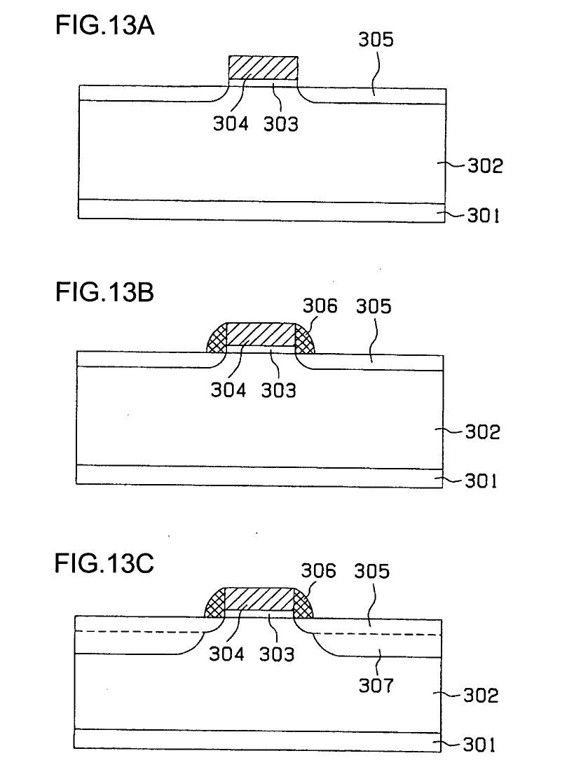

Conventionally, a method of manufacturing a MOS transistor, which is explained below, is known. Taking an N channel MOS transistor as an example, the structure and the method of manufacturing thereof will be briefly explained with reference to FIG. 13.

A p-well region 302 having a carrier density of 3×10¹⁶/cm³ is formed in an n-type silicon substrate 301 having a carrier density of 2×10¹⁵/cm³. Next, ions of boron are implanted as the channel doping ion and a gate oxide layer 303 having a thickness of 20 nm is formed by a thermal oxidation method. Next, phosphorus doped poly silicon having a thickness of 400 nm is deposited by a CVD (Chemical Vapor Deposition) method. Next, a gate region 304 is formed by a conventional photolithography process and a conventional dry etching process. Next, by performing a phosphorus ion implantation process for N-channel, a self-aligned LDD region 305 is formed (FIG. 13(a)).

Next, after forming the oxide layer by the CVD method, a highly anisotropic dry etching process is performed. A highly isotropic oxide layer is formed by using the CVD method, while an oxide layer is left only at both sides of the poly silicon by using the highly anisotropic dry etching method, thus forming sidewall regions 306 (FIG. 13(b)).

And next, phosphorus is implanted with a dose of about 5×10E15/cm², thus forming source/drain regions 307. Moreover, because the regions contain a high concentration of impurity and exhibit low resistivity, the regions are also used for electrical-wiring, which couples each element.

Finally, a lamp annealing process for activating the implanted impurity is performed, thus forming an N channel MOS transistor (FIG. 13 (c)).

Although a process of manufacturing an N channel MOS transistor is described above, this process also becomes a process of manufacturing a P channel MOS transistor by changing ion sources in an ion implantation process.

With the demand for down-sizing of MOS transistors and for increasing the speed of MOS transistors, a salicide (Self-aligned Silicide) technology, which simultaneously suicides the surface of the gate region and the source/drain regions in a self-aligned manner, is commonly used to reduce resistivity in the gate region and the source/drain regions. With adopting this technology, each electrode surface is covered with a low resistive silicide such as titanium silicide (TiSi₂) and cobalt silicide (CoSi₂), thus reducing the sheet resistivity thereof.

However, when a thermal processing is performed to a Si substrate covered with a Co layer, Co diffuses into the Si substrate to form a compound of CoSi. In this case, Co easily diffuses deep into the substrate by tracing residual defects of linear shape, which remain inside the Si substrate. Moreover, Co tends to condense around the defects, consequently, a phenomenon that Co₂Si grows unusually through the defects deeply into the substrate occurs. If the unusually grown Co₂Si reaches the vicinity of the P/N junction of the well and the diffusion layer, a junction leakage occurs therefrom.

In order to solve this problem, in the Patent Document 1, a technique of implanting an impurity into source/drain in separate two times is adopted. Namely, in this technique, a first impurity implanting is performed so as to implant deeply into the source/drain with a light impurity concentration. Accordingly, the residual defects are reduced by lowering the impurity concentration of the source/drain regions, thus suppressing the unusual growth of Co₂Si and the junction leakage caused by the unusual growth.

However, if simply reducing the impurity concentration of the source/drain regions, the contact resistance with the CoSi₂ layer formed thereon increases. So, in the invention of the Patent Document 1, a second impurity implanting is performed shallowly in depth and with an impurity concentration as high as possible. Namely, a heavily doped layer containing many residual defects is formed underneath the CoSi₂ layer. Namely by causing many defects to occur over the whole surface of the heavily doped layer and causing the unusual growth of the Co₂Si to occur uniformly over the whole surface of the heavily doped layer and terminate there, a part of the Co₂Si is prevented from growing prominently deep, thereby suppressing the junction leakage more effectively.

In addition, the Patent Document 1 discloses that a second-time ion implanting for forming the heavily doped layer needs to be performed with a dose amount of at least 1×10E15/cm² to reduce the unusual growth of each Co₂Si.

[Patent Document 1]

Re-publication patent WO 99/16116

[Problem to be Solved by the Invention]

Si becomes amorphous by implanting with a high impurity concentration. Then, for restoring the amorphized Si and activating the implanted impurity, for example, a RTA (rapid thermal annealing) is performed at 1020° C. With this annealing, solid phase epitaxial growth arises to restore the defects. However, the solid phase epitaxial growth exhibits a plane direction to leave small defects along the plane direction of <111>.

In recent years, an isolation technology using a shallow trench isolation (hereinafter referred to “STI”) has been adopted. As for the STI, a trench groove is formed in the boundary of elements to embeded SiO₂ in the trench groove, thus isolating the elements.

To manufacture a device having high breakdown voltage, a gate region having a relatively thick layer may be formed in a gate oxidization step. Therefore, in such a gate oxidization step, oxidization growth in the trench groove of the STI is also accelerated to cause a strong stress to be retained inside the silicon substrate.

Then, a huge dislocation loop originating from a tiny residual defect in the source/drain regions may occur to extend to the bottom edge portion of the trench groove. This huge dislocation loop has a problem of crossing the P/N junction and generating a leakage current.

The present invention has been made in view of this problem, and an object of the invention is to provide a semiconductor device and a method of manufacturing the same, which can prevent the generation of the junction leakage by forming a diffusion layer with a concentration as low as possible or by forming the diffusion layer by ion implanting of two times with two different impurity concentrations so as to make the concentration of a heavily doped layer as low as possible and the depth of the heavily doped layer as shallow as possible.

[Means to Solve the Problem]

A semiconductor device according to the present invention comprises: a semiconductor region, in which an impurity of one conductivity type is doped; a gate insulation layer, formed on the semiconductor region; a gate electrode, formed on the gate insulation layer; a lightly doped layer, formed in a region from the principal surface to a first depth of the semiconductor region, in which a first impurity of the other conductivity type is implanted with a first dose amount; and a heavily doped layer, formed in a region from the principal surface of the semiconductor region to a second depth, which is shallower than the first dept, in which a second impurity of the other conductivity type is implanted into the semiconductor region with a second dose amount in a range of the first dose amount or more to 1×10E15/cm² or less.

According to such a structure, the gate insulation layer is formed on the semiconductor region, in which the impurity of one conductivity type is doped, and the gate electrode is formed on the gate insulation layer. The diffusion layer has the lightly doped layer and the heavily doped layer. The lightly doped layer is formed in the region from the principal surface to the first depth by implanting the first impurity of the other conductivity type into the semiconductor region with the first dose amount. On the other hand, the heavily doped layer is formed in the region from the principal surface to the second depth, which is shallower than the first depth, by implanting the second impurity of the other conductivity type into the semiconductor region with the second dose amount in a range of the first dose amount or more to 1×10E15/cm² or less. Because the heavily doped layer is ion implanted with the second dose amount of 1×10E15/cm² or less, the residual defects can be prevented from occurring in the annealing process for activating the diffusion layer. Accordingly, the generation of the huge dislocation loop, which crosses the P/N junction, is suppressed, thereby reducing the occurrence probability of the junction leakage.

Moreover, a semiconductor device according to the present invention comprises: a semiconductor region, in which an impurity of one conductivity type is doped; a gate insulation layer, formed on the semiconductor region; a gate electrode, formed on the gate insulation layer; a lightly doped layer, formed in a region from the principal surface to a first depth of the semiconductor region, in which a first impurity of the other conductivity type is implanted into the semiconductor region with a first dose amount; and a heavily doped layer, formed in the depth direction from the principal surface of the semiconductor region, in which a second impurity of the other conductivity type is implanted into the semiconductor region with a second dose amount so that a peak position of the concentration exists at a second depth position, which is shallower than the first depth by 0.15 μm or more.

According to such a structure, the gate insulation layer is formed on the semiconductor region, in which the impurity of one conductivity type is doped, and the gate electrode is formed on the gate insulation layer. The diffusion layer has the lightly doped layer and the heavily doped layer. The lightly doped layer is formed in the region from the principal surface of the semiconductor region to the first depth by implanting the first impurity of the other conductivity type into the semiconductor region with the first dose amount. On the other hand, the heavily doped layer is formed by implanting the second impurity of the other conductivity type into the semiconductor region with the second dose amount so that the peak position of the concentration exists at the second depth, which is shallower than the first depth by 0.15 μm or more. Because the first depth, namely the P/N junction position, is separated by 0.15 μm or more from the peak position of the concentration of the heavily doped layer, even when the residual defects arise in the heavily doped layer, the occurrence probability of the huge dislocation loop, which crosses the P/N junction, is very low, thereby the junction leakage can be suppressed.

Moreover, a semiconductor device according to the present invention comprises: a semiconductor region, in which an impurity of one conductivity type is doped; a gate insulation layer, formed on the semiconductor region; a gate electrode, formed on the gate insulation layer; a lightly doped layer, formed in a region from the principal surface to a first depth of the semiconductor region, in which a first impurity of the other conductivity type is implanted into the semiconductor region with a first dose amount; and a heavily doped layer, formed in the depth direction from the principal surface of the semiconductor region, in which a second impurity of the other conductivity type is implanted into the semiconductor region with a second dose amount in a range of the first dose amount or more to 1×10E15/cm² or less so that a peak position of the concentration exists at the second depth position, which is shallower than the first depth by 0.15 μm or more.

According to such a structure, the gate insulation layer and the gate electrode are formed in the semiconductor region. The diffusion layer has the lightly doped layer and the heavily doped layer. The lightly doped layer is formed in the region from the principal surface to the first depth by implanting the first impurity of the other conductivity type with the first dose amount. On the other hand, the heavily doped layer is formed by implanting the second impurity of the other conductivity type with the second dose amount in a range of the first dose amount or more to 1×10E15/cm² or less so that the peak position of the concentration exists at the second depth position, which is shallower than the first depth by 0.15 μm or more. Namely, the residual defects in the heavily doped layer are suppressed, and even if the residual defects arise, the distance from the residual defects to the P/N junction is 0.15 μm or more, which is long enough to suppress the generation of the huge dislocation loop, which crosses the P/N junction, thereby the occurrence probability of the junction leakage can be reduced.

Moreover, the one conductivity type is N-type and the other conductivity type is P-type.

According to such a structure, the N-type transistor having reduced junction leakage is obtained.

Moreover, the second impurity is arsenic.

According to such a structure, even with the heavily doped layer containing the impurity of arsenic, which is liable to produce a defect by an ion implantation, the generation of the residual defects is suppressed, and the residual defects arise at the position sufficiently distant from the P/N junction, thereby the junction leakage can be reduced sufficiently.

Moreover, the semiconductor device includes a trench structure, which isolates the semiconductor region.

According to such a structure, the generation of the huge dislocation loop originating from the residual defects of the heavily doped layer to the edge portion of the trench structure can be suppressed, thereby the junction leakage can be reduced.

Moreover, a method of manufacturing a semiconductor device according to the present invention comprises: forming a semiconductor region by doping an impurity of one conductivity type; forming a gate insulation layer on the semiconductor region; forming a gate electrode on the gate insulation layer; forming a lightly doped layer in a region from the principal surface to a first depth of the semiconductor region by implanting a first impurity of the other conductivity type into the semiconductor region with a first dose amount; and forming a heavily doped layer in a region from the principal surface of the semiconductor region to a second depth, which is shallower than the first depth, by implanting a second impurity of the other conductivity type into the semiconductor region with a second dose amount in a range of the first dose amount or more to 1×10E15/cm² or less.

According to such a structure, the gate insulation layer is formed on the semiconductor region, and the gate electrode is formed on the gate insulation layer. The lightly doped layer is formed at first in the storing layer, which has the lightly doped layer and the heavily doped layer. The heavily doped layer is formed in the region from the principal surface to the second depth, which is shallower than the first depth by implanting the second impurity of the other conductivity type into the semiconductor region with a second dose amount in a range of the first dose amount or more to 1×10E15/cm² or less. Because the heavily doped layer is ion-implanted with the second dose amount of 1×10E15/cm² or less, the residual defects can be prevented from arising in the annealing process for activating the diffusion layer. Accordingly, the generation of the huge dislocation loop, which crosses the P/N junction, is suppressed, thereby reducing the occurrence probability of the junction leakage.

Moreover, a method of manufacturing a semiconductor device according to the present invention comprises: forming a semiconductor region by doping an impurity of one conductivity type; forming a gate insulation layer on the semiconductor region; forming a gate electrode on the gate insulation layer; forming a lightly doped layer in a region from the principal surface to a first depth of the semiconductor region by implanting a first impurity of the other conductivity type into the semiconductor region with a first dose amount; and forming a heavily doped layer in the depth direction from the principal surface of the semiconductor region by implanting a second impurity of the other conductivity type into the semiconductor region with a second dose amount so that a peak position of the concentration exists at a second depth position, which is shallower than the first depth by 0.15 μm or more.

According to such a structure, the gate insulation layer is formed on the semiconductor region and the gate electrode is formed on the gate insulation layer. The lightly doped layer is formed at first in the diffusion layer, which has the lightly doped layer and the heavily doped layer. Next, the heavily doped layer is formed by implanting the second impurity of the other conductivity type into the semiconductor region with the second dose amount. In this case, the heavily doped layer is formed so that the peak position of the concentration exists at the second depth, which is shallower than the first depth by 0.15 μm or more. Accordingly, the distance from the residual defects that arise in the heavily doped layer to the P/N junction is sufficiently long, and the occurrence probability of the huge dislocation loop, which crosses the P/N junction, is very low, thereby the junction leakage can be suppressed.

Moreover, a method of manufacturing a semiconductor device according to the present invention comprises: forming a semiconductor region by doping an impurity of one conductivity type; forming a gate insulation layer on the semiconductor region; forming a gate electrode on the gate insulation layer; forming a lightly doped layer in a region from the principal surface to a first depth of the semiconductor region by implanting a first impurity of the other conductivity type into the semiconductor region with a first dose amount; and forming a heavily doped layer in the depth direction from the principal surface of the semiconductor region by implanting a second impurity of the other conductivity type with a second dose amount in a range of the first dose amount or more to 1×10E15/cm² or less so that the peak position of the concentration exists at a second depth position, which is shallower than the first depth by 0.15 μm or more.

According to such a structure, the gate insulation layer is formed on the semiconductor region and the gate electrode is formed on the gate insulation layer. The lightly doped layer is formed at first in the storing layer, which has the lightly doped layer and the heavily doped layer. The heavily doped layer is formed in the semiconductor region by implanting the second impurity of the other conductivity type into the semiconductor region with the second dose amount in a range of the first dose amount or more to 1×10E15/cm² or less. In this case, the heavily doped layer is formed so that the peak position of the concentration exists at the second depth, which is shallower than the first depth by 0.15 μm or more. Accordingly, the generation of the residual defects in the heavily doped layer is suppressed, and even if the residual defects arise, the distance between the residual defect and the P/N junction is sufficiently long, and the occurrence probability of the huge dislocation loop, which crosses the P/N junction, is very low, thereby the junction leakage can be suppressed.

Moreover, a semiconductor device according to the present invention comprises: a semiconductor region, in which an impurity of one conductivity type is doped; a gate insulation layer, formed on the semiconductor region; a gate electrode, formed on the gate insulation layer; and a heavily doped layer, formed by implanting a second impurity of the other conductivity type into the semiconductor region with a second dose amount of 1×10E15/cm² or less.

According to such a structure, the gate insulation layer is formed on the semiconductor region, in which the impurity of one conductivity type is doped, and the gate electrode is formed on the gate insulation layer. The heavily doped layer, which becomes a diffusion layer, is formed in the region to the second depth by implanting the second impurity of the other conductivity type into the semiconductor region with the second dose amount of 1×10E15/cm² or less. Because the heavily doped layer is ion-implanted with the second dose amount of 1×10E15/cm² or less, the residual defects can be prevented from arising in the annealing process for activating the diffusion layer. Accordingly, the generation of the huge dislocation loop, which crosses the P/N junction, is suppressed, thereby reducing the occurrence probability of the junction leakage.

[Embodiment of the Invention]

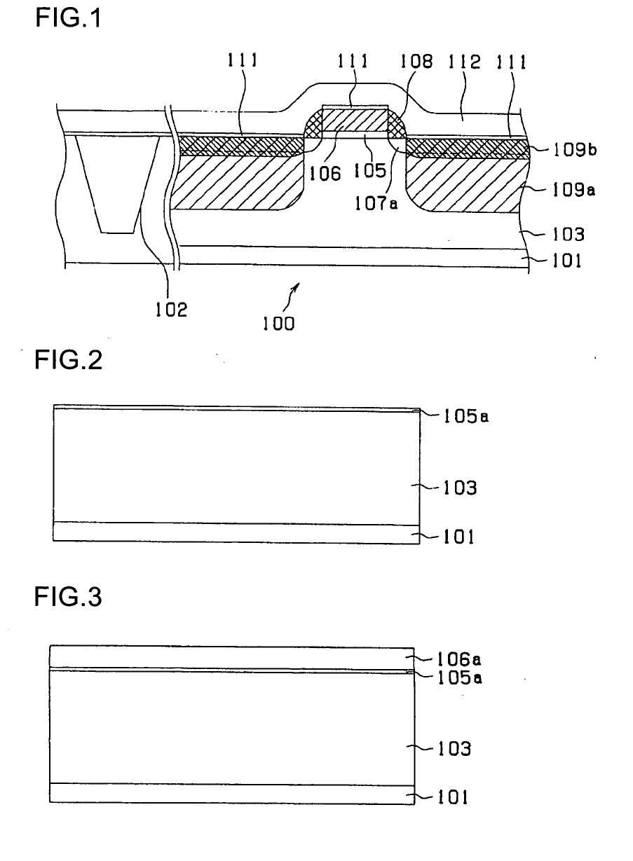

Hereinafter, an embodiment of the present invention will be described in detail with reference to drawings. FIG. 1 is a sectional view schematically showing a semiconductor device according to an embodiment of the present invention. The embodiment is applied to an N channel type MOS transistor (NMOS transistor).

The semiconductor device shown in FIG. 1 includes an NMOS transistor 100, which has offset regions. The NMOS transistor 100 is isolated by a trench 102. A p-well region 103 is formed on an n-type silicon semiconductor substrate 101. Above the p-well region 103, a gate electrode 106 is formed via a gate oxide layer 105. Sidewall regions 108 are formed on the side walls of the gate electrode 106, and in the vicinity of the surface of the p-well region 103, which is underneath the sidewall regions 108, N-offset regions 107a are formed. Then, p⁺ source/drain regions 109 are formed in a sub-surface region of the p-well region 103, in which the gate electrode 106 and the sidewall regions 108 are not formed. A titanium silicide layer 111 is formed on the gate electrode 106 and on the source/drain regions 109, while a protection layer 112 is formed on the titanium silicide layer 111 and the sidewall regions 108.

As for the embodiment, the p⁺ source/drain regions 109 includes a lightly doped layer 109a, whose depth from the principal surface of the semiconductor substrate (hereinafter simply referred to “depth”) is deep and whose impurity concentration is low, and a heavily doped layer 109b, whose depth is shallow and whose impurity concentration is high. Then as for the embodiment, the dose amount in a step of implanting an impurity for forming the heavily doped layer 109b (hereinafter referred to “shallow implanting step”) is set to 1×10E15/cm² or less. In addition, the dose amount in the shallow implanting step is set to more than the dose amount in a step of implanting the impurity for forming the lightly doped layer 109a (hereinafter referred to “deep implanting step”).

The difference between the depth to the P/N junction defined by the depth of the lightly doped layer 109a and the depth of the peak position of the impurity concentration in the heavily doped layer 109b, namely the length between the peak position of the impurity concentration in the heavily doped layer 109b and the P/N junction is set to 0.15 μm or more.

As for the embodiment configured in this way, the depth of the P/N junction is defined by the lightly doped layer 109a, and the diffusion resistance value is defined by the concentration of the heavily doped layer 109b. Moreover, because the impurity concentration of the lightly doped layer 109a is sufficiently set to low, the residual defects seldom arise in the annealing process for amorphizing Si and implanting the impurity.

As for the embodiment, because the dose amount of the heavily doped layer 109b in the shallow implantation step is set to 1×10E15/cm² or less, the generation of the residual defects in the annealing process for amorphizing Si and implanting the impurity can be suppressed sufficiently. Accordingly, even if the thickness of the gate oxide layer 105 is formed relatively thick and the oxidization growth of the trench 102 is accelerated, the generation of the huge dislocation loop originating from the residual defects that arise in the heavily doped layer 109b is suppressed, thereby the occurrence probability of the junction leakage can be reduced significantly.

Moreover, the length between the peak position of the impurity concentration in the heavily doped layer 109b and the P/N junction is set to 0.15 μm or more. Accordingly, even if the residual defects are present in the heavily doped layer 109b, the distance from the residual defects to the P/N junction is long enough to suppress the generation of the huge dislocation loop, which crosses the P/N junction, thereby further reducing the occurrence probability of the junction leakage.

Therefore, in a case where an IC is configured using the NMOS transistor 100 according to the embodiment, an IC leakage current at the time of standby can be suppressed sufficiently, which is very effective in reducing the power consumption.

As for the above-described embodiment, an NMOS transistor is explained as an example, however, it is obvious that a PMOS transistor can be configured in the same way.

Next, a method of manufacturing the NMOS transistor 100 shown in the semiconductor device of FIG. 1 will be described with reference to FIGS. 2 through 9. FIGS. 2 through 9 are process drawings illustrating process steps of the manufacturing method with reference to cross-section structures.

At first, an oxide layer (not shown) having a thickness of 50 nm is formed by performing a thermal processing of the surface of the n-type silicon semiconductor substrate 101 having a resistivity of 10 ohm-cm in 95% steam atmosphere at 900° C. for 30 minutes. The oxide layer is needed to prevent a phenomenon that the ions implanted in the ion implantation step exhibits an unusual distribution. Next, boron (B) is implanted by an ion implantation method. The acceleration energy for boron (B) atom is set to 70 keV, while the amount of ion implantation is set to 1×10E13/cm² in terms of the number of the ions.

Next, a thermal diffusion is performed in nitrogen atmosphere at 1100° C. for 7 hours. With the thermal processing, the p-well region 103 having a depth of 2.5 μm is formed.

Next, the oxide layer formed on the surface of the n-type silicon semiconductor substrate 101 is removed by etching, and an oxide layer (not shown) is again formed by performing the thermal oxidation processing. The oxide layer is needed to prevent a phenomenon that the ions implanted in the ion implantation step exhibits an unusual distribution.

Next, ions of boron (B) are implanted to adjust the threshold voltage of the MOS device. The acceleration energy for the boron (B) atom is set to 70 keV, while the amount of ion implantation is set to 3×10E12/cm² in terms of the number of ions.

Next, after removing the oxide layer formed on the surface of the n-type silicon semiconductor substrate 101 by etching using a buffer hydrofluoric acid, a gate oxide layer 105a having a thickness of 15 nm is formed by the thermal processing in 95% steam atmosphere at 820° C. for 15 minutes. FIG. 2 shows this state.

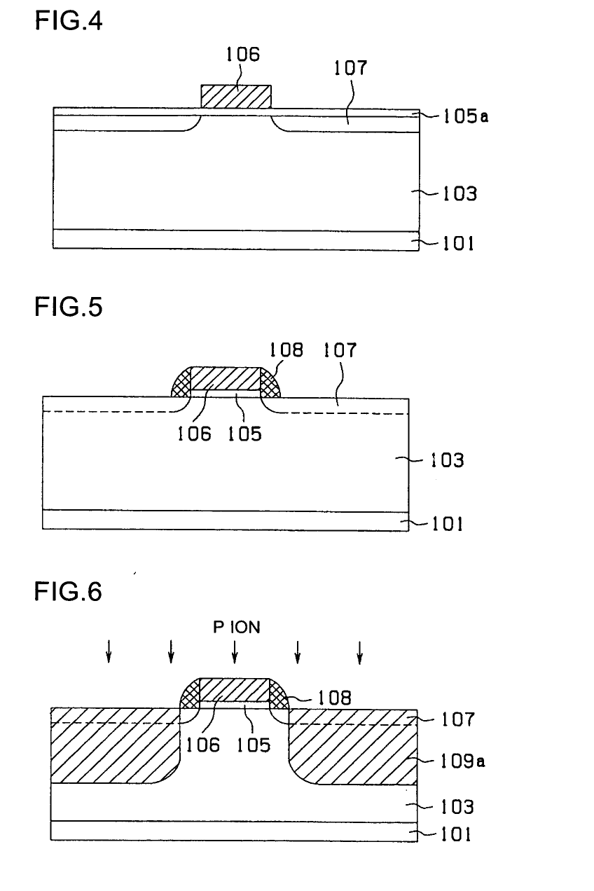

Next, a gate electrode layer 10a is formed by depositing phosphorus (P) doped poly silicon to a thickness of 400 nm by the CVD method (FIG. 3). Then, a gate electrode 106 having a width of 0.7 μm is formed by a conventional photolithography etching step (FIG. 4).

Next, as shown in a FIG. 4, an LDD region 107 is formed by a phosphorus (P) ion implantation step. The acceleration energy is set to 30 keV, while the amount of ion implantation is set to 1×10E13/cm² in terms of the number of ions.

Next, a silicon oxide (SiO₂) is deposited over the whole surface by the CVD method using silane and laughing gas as source gases. Then, a part of the silicon oxide and the gate insulation layer 105a are removed by the anisotropic dry etching, thus forming sidewall regions 108 having a width of 0.3 μm as shown in FIG. 5.

Next, source/drain regions 109 are formed. As for the embodiment, a step of forming the source/drain regions is performed by two times of ion implantation. Namely, the impurity implantation step for forming the lightly doped layer 109a (deep implantation step) is carried out at first. In this step, for example, phosphorus (P) ion implantation is carried out with a dose amount of 3.5×10E13/cm² and an acceleration energy of 65 keV. Accordingly, as shown in FIG. 6, the lightly doped layer 109a having a deep depth is formed.

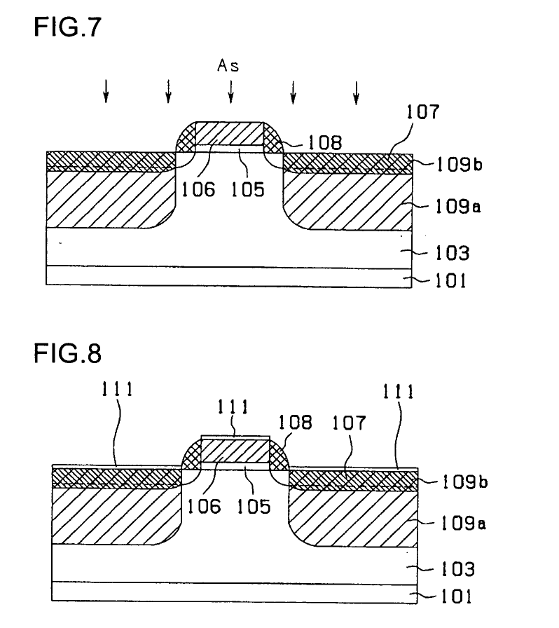

Next, the shallow implantation step for forming the heavily doped layer 109b is carried out. In this step, for example, arsenic (As) ion implantation is carried out with a dose amount of 1×10E15/cm² and an acceleration energy of 40 keV. Accordingly, as shown in FIG. 7, the heavily doped layer 109a having a shallow depth is formed.

Next, a titanium layer, which is a high melting-point metal, is formed using the sputtering method. With the subsequent thermal processing, the titanium and the poly silicon thereunder react to form a titanium silicide layer 111. Then, with the selective etching of the titanium, the titanium on the oxide layer is removed (FIG. 8).

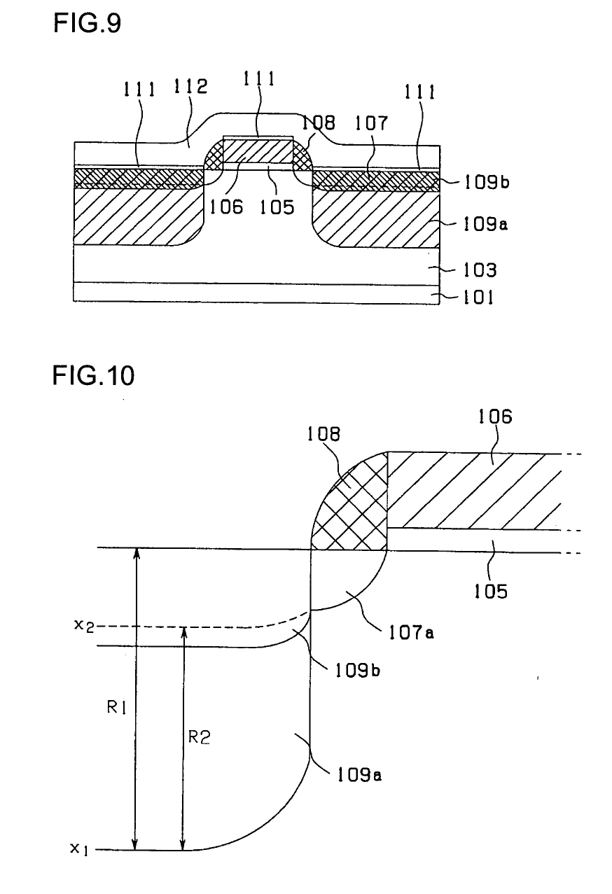

Next, by performing the annealing process, the impurity is activated to form the NMOS transistor 100. Finally, a silicon nitride (Si₃N₄) layer 112 is deposited on the whole surface as a protection layer or an interlayer insulation layer (FIG. 9). The layer 112 may be formed by forming the silicon oxide (SiO₂) layer on the NMOS transistor 100 at first, and then depositing the silicon nitride layer thereon.

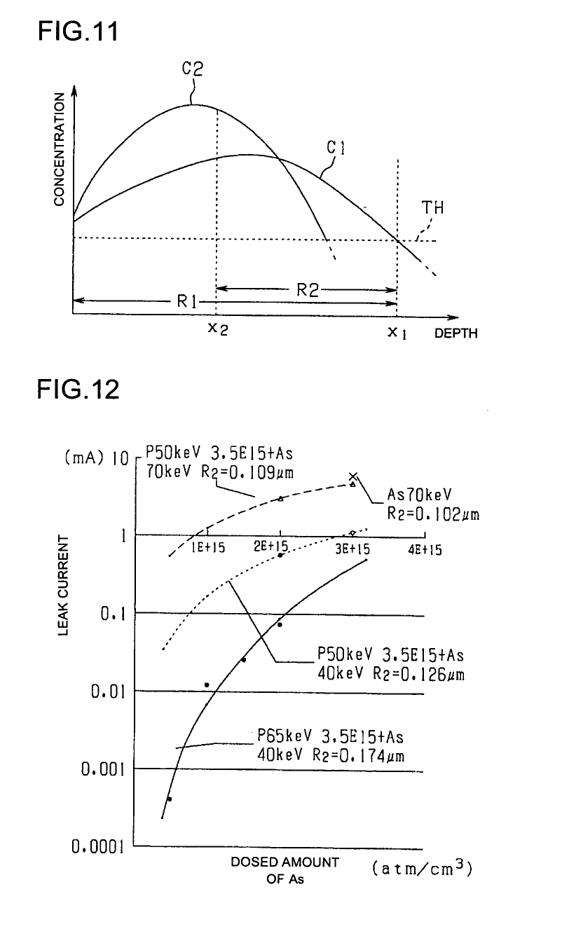

FIG. 10 is an expanded explanatory drawing showing the vicinity of the source/drain regions 109. FIG. 11 is a graph showing the concentration distribution in the source/drain regions 109, wherein the horizontal axis represents the depth, while the vertical axis represents the impurity concentration.

A curve C1 in FIG. 11 shows a concentration distribution of the impurity by the first deep implantation step in the diffusion layer formation step. A concentration TH represents the impurity concentration of the p-well region 103. The depth x1, a position where the concentration of the curve C1 reaches the concentration of TH, corresponds to the depth of the P/N junction. In FIG. 10, the depth x1 represents the boundary (P/N junction) position of the lightly doped layer 109a, formed in the deep implantation step, and the p-well region 103.

On the other hand, a curve C2 in FIG. 11 shows the concentration distribution of the impurity by the shallow implantation step. A depth x2 in FIG. 11 represents the peak position of the concentration in the heavily doped layer 109b. Because the dose amount in the shallow implantation is set to 1×10E15/cm², the generation of the residual defects is reduced significantly even if the annealing process for activating the diffusion layer is performed.

The difference of the depth x1 and the depth x2 (x1−x2=R2) is the length from the P/N junction to the peak position of the impurity concentration in the heavily doped layer 109b, which is controlled 0.15 μm or more by setting the ion acceleration energy and the dose amount for each of the deep implantation step and the shallow implantation step as described above. FIG. 10 shows the length from the P/N junction to the peak position of the impurity concentration in the heavily doped layer 109b. The residual defects that arise in the heavily doped layer 109b arise toward the principal surface side in the semiconductor substrate from the dashed line in FIG. 10. Namely, because the residual defects arise at the position sufficiently distant from the P/N junction, even if the residual defects arise in the heavily doped layer 109b, the occurrence probability of the junction leakage is very small.

Accordingly, as for the embodiment, the impurity implantation step for forming the source/drain regions of the transistor is divided into two steps: an implantation with a deep depth and a low impurity concentration, and an implantation with a shallow depth and a high impurity concentration. The dose amount of the shallow implantation step is controlled so as to be 1×10E15/cm² or less, and the length between the P/N junction, formed by the deep implantation, and the peak position of the impurity concentration of the heavily doped layer, formed by the shallow implantation, is controlled 0.15 μm or more. Accordingly, even if the annealing process is performed for activating the diffusion layer, the generation of the residual defects in the heavily doped layer is prevented. Moreover, even if the residual defects arise, the distance from the P/N junction to the residual defects is long enough to suppress the generation of the huge dislocation loop, thereby the occurrence probability of the junction leakage can be reduced significantly.

As for the above-described embodiment, the implantation step with a deep depth and a low impurity concentration is carried out at first and then the implantation step with a shallow depth and a high impurity concentration is carried out for the two times of ion implantation step for forming the source/drain regions, however, the shallow implantation step may be carried out at first, followed by the deep implantation step.

Furthermore, the source/drain regions may be formed by one time of ion implantation step with a dose amount of 1×10E15/cm² or less.

Moreover, in the above-described embodiment, an NMOS transistor is explained as an example, however, it is obvious that the embodiment can be also applicable to a P channel MOS transistor by changing the impurity to be doped.

For example, when applying to a P channel MOS transistor, in the ion implantation step for forming a deep depth and a light impurity concentration, ions of boron (B) are implanted by setting a dose amount of 1.5×10E15/cm² and an acceleration energy of 8 keV. Then, in an implantation with a shallow depth and a high impurity concentration, ions of fluoride boron (BF₂) are implanted by setting a dose amount of 5×10E14/cm² and an acceleration energy of 25 keV.

According to the present invention, the ion implantation condition, such as an impurity to be doped, an acceleration energy and a dose amount thereof, can be changed suitably, except that the dose amount is set 1×10E15/cm² or less in the shallow implantation step, and that the length from the P/N junction to the peak position of the impurity concentration in the heavily doped layer is controlled 0.15 μm or more.

(Embodiment)

A median value of the leakage current is measured by configuring a logic IC product combined with about 1 M-bit SRAM by employing the NMOS transistor according to the above-described embodiment. FIG. 12 shows the result of this experiment.

As for the condition in the step of forming the source/drain regions, the amount of arsenic (As) implantation in the shallow implantation step is varied, and the acceleration energy of phosphorus (P) in the deep implantation step and the acceleration energy of arsenic (As) in the shallow implantation step are varied for each amount of the implantation. Then, the relationship between the dose amount of the impurity in the shallow implantation step and the median value of the IC leakage current at the time of standby is derived.

FIG. 12 is a graph showing the relationship between the dose amount of arsenic (As) and the median value of the IC leakage current at the time of standby, based on the result of this experiment. FIG. 12 also shows examples of a combination of the depth (implantation energy) of the arsenic (As) and the implantation condition of the phosphorus (P) that is implanted deeply. R2 in the FIG. 12 represents the distance between the P/N junction and the concentration peak position of the heavily doped layer, formed in the implantation step of arsenic (As).

As clearly shown in FIG. 12, the leakage current is dependent on the amount of the arsenic (As) implantation in the shallow implantation step, and it is understood that the leakage current rapidly decreases as the dose amount becomes 1×10E15/cm² or less. Moreover, when combining the shallow implantation step with the deep implantation step using phosphorus (P), as shown by the dotted line, the leakage current can be improved by controlling the concentration peak position of the heavily doped layer at a shallower position compared to the condition of the dashed line. Furthermore, as shown by the solid line, a further improved effect on the leakage current is obtained by deepening the P/N junction by increasing the acceleration energy in the deep implantation step using phosphorus (P). Namely, this indicates the effect of setting the distance between the peak position of the impurity concentration of the heavily doped layer in the shallow implantation step and the P/N junction to 0.15 μm or more.

As for the embodiment, the leakage current of the logic product used for the experiment can be stably reduced to 1 μA or less.

Therefore, when configuring a product using the present invention, the reduction of power consumption can be realized by suppressing the leakage current. Namely, the standby current can be reduced for the product that uses the NMOS transistor according to the present invention, and this is extremely useful for a product that uses a battery, such as a portable apparatus.

The present invention is not limited to the above-described embodiment, and various modifications and alterations can be made without departing from the spirit and scope of the invention.

### BRIEF DESCRIPTION OF THE DRAWINGS

[FIG. 1] FIG. 1 is a cross-sectional view showing schematically a semiconductor device according to an embodiment of the present invention.

[FIG. 2] FIG. 2 is a process drawing illustrating a process step of a manufacturing method with reference to a cross-section structure.

[FIG. 3] FIG. 3 is a process drawing illustrating a process step of the manufacturing method with reference to a cross-section structure.

[FIG. 4] FIG. 4 is a process drawing illustrating a process step of the manufacturing method with reference to a cross-section structure.

[FIG. 5] FIG. 5 is a process drawing illustrating a process step of the manufacturing method with reference to a cross-section structure.

[FIG. 6] FIG. 6 is a process drawing illustrating a process step of the manufacturing method with reference to a cross-section structure.

[FIG. 7] FIG. 7 is a process drawing illustrating a process step of the manufacturing method with reference to a cross-section structure.

[FIG. 8] FIG. 8 is a process drawing illustrating a process step of the manufacturing method with reference to a cross-section structure.

[FIG. 9] FIG. 9 is a process drawing illustrating a process step of the manufacturing method with reference to a cross-section structure.

[FIG. 10] FIG. 10 is an expanded explanatory drawing showing the vicinity of source/drain regions 109.

[FIG. 11] FIG. 11 is a graph showing a concentration distribution in the source/drain regions 109.

[FIG. 12] FIG. 12 is a graph showing a result of an experiment.

[FIG. 13] FIG. 13 is a process drawing of a conventional art.

### REFERENCE NUMERALS

100—NMOS transistor,

101—n-type silicon semiconductor substrate,

103—p-well region,

105—Gate oxide layer,

106—Gate electrode,

109—Source/drain regions,

109a—Lightly doped layer,

109b—Heavily doped layer.

1. A semiconductor device, comprising:
a semiconductor region in which an impurity of one conductivity type is doped;
a gate insulation layer formed on the semiconductor region;
a gate electrode formed on the gate insulation layer;
a lightly doped layer, formed in a region from principal surface of the semiconductor region to a first depth of the semiconductor region, in which a first impurity of another conductivity type is implanted into the semiconductor region with a first dose amount; and
a heavily doped layer, formed in a region from the principal surface of the semiconductor region to a second depth, in which a second impurity of the another conductivity type is implanted into the semiconductor region with a second dose amount in a range of the first dose amount or more to 1×10¹⁵/cm² or less;
wherein the second depth is less than the first depth.

2. A semiconductor device, comprising:
a semiconductor region in which an impurity of one conductivity type is doped;
a gate insulation layer formed on the semiconductor region;
a gate electrode formed on the gate insulation layer;
a lightly doped layer, formed in a region from a principal surface of the semiconductor region to a first depth of the semiconductor region, in which a first impurity of another conductivity type is implanted into the semiconductor region with a first dose amount; and
a heavily doped layer, formed in a depth direction from the principal surface of the semiconductor region, in which a second impurity of the another conductivity type is implanted into the semiconductor region with a second dose amount so that a peak position of a concentration of the second impurity exists at a second depth position, the second depth position being less than the first depth by 0.15 μm or more.

3. A semiconductor device, comprising:
a semiconductor region in which an impurity of one conductivity type is doped;
a gate insulation layer formed on the semiconductor region;
a gate electrode formed on the gate insulation layer;
a lightly doped layer, formed in a region from a principal surface of the semiconductor region to a first depth of the semiconductor region, in which a first impurity of another conductivity type is implanted into the semiconductor region with a first dose amount; and
a heavily doped layer, formed in a depth direction from the principal surface of the semiconductor region, in which a second impurity of another conductivity type is implanted into the semiconductor region with a second dose amount in a range of the first dose amount or more to 1×10¹⁵/cm² or less so that a peak position of a concentration of the second impurity exists at a second depth position, the second depth Position being less than the first depth by 0.15 μm or more.

4. The semiconductor device according to claim 1, wherein the one conductivity type is N-type and the another conductivity type is P-type.

5. The semiconductor device according to claim 1, wherein the second impurity is arsenic.

6. The semiconductor device according to claim 1, further comprising a trench structure that isolates the semiconductor region.

7. A method of manufacturing a semiconductor device, comprising:
forming a semiconductor region by doping an impurity of one conductivity type;
forming a gate insulation layer on the semiconductor region;
forming a gate electrode on the gate insulation layer,
forming a lightly doped layer in a region from a principal surface of the semiconductor region to a first depth of the semiconductor region by implanting a first impurity of another conductivity type into the semiconductor region with a first dose amount; and
forming a heavily doped layer in a region from the principal surface of the semiconductor region to a second depth, which is less than the first depth, by implanting a second impurity of the another conductivity type into the semiconductor region with a second dose amount in a range of the first dose amount or more to 1×10¹⁵/cm² or less.

8. A method of manufacturing a semiconductor device, comprising:
forming a semiconductor region by doping an impurity of one conductivity type;
forming a gate insulation layer on the semiconductor region;
forming a gate electrode on the gate insulation layer;
forming a lightly doped layer in a region from a principal surface to a first depth of the semiconductor region by implanting a first impurity of another conductivity type into the semiconductor region with a first dose amount; and
forming a heavily doped layer in a depth direction from the principal surface of the semiconductor region by implanting a second impurity of the another conductivity type into the semiconductor region with a second dose amount so that a peak position of a concentration of the second impurity exists at a second depth position, the second depth position being less than the first depth by 0.15 μm or more.

9. A method of manufacturing a semiconductor device, comprising:
forming a semiconductor region by doping an impurity of one conductivity type;
forming a gate insulation layer on the semiconductor region;
forming a gate electrode on the gate insulation layer;
forming a lightly doped layer in a region from a principal surface to a first depth of the semiconductor region by implanting a first impurity of another conductivity type into the semiconductor region with a first dose amount; and
forming a heavily doped layer in a depth direction from the principal surface of the semiconductor region by implanting a second impurity of the another conductivity type into the semiconductor region with a second dose amount in a range of the first dose amount or more to 1×10¹⁵/cm² or less so that a peak position of a concentration of the second impurity exists at a second depth position, the second depth being less than the first depth by 0.15 μm or more.

10. A semiconductor device, comprising:
a semiconductor region in which an impurity of one conductivity type is doped;
a gate insulation layer formed on the semiconductor region;
a gate electrode formed on the gate insulation layer; and
a heavily doped layer, formed by implanting a second impurity of another conductivity type into the semiconductor region with a second dose amount of 1×10¹⁵/cm² or less.
